(19) United States
(12) Patent Application Publication
(10) Pub. No.: US 2025/0060421 A1
(43) Pub. Date: Feb. 20, 2025

(54) METHOD AND SYSTEM FOR AC FAULT DETECTION

(71) Applicant: Raytheon Systems Limited, Harlow (GB)

(72) Inventor: David Calkin, Glenrothes (GB)

(21) Appl. No.: 18/800,668

(22) Filed: Aug. 12, 2024

(30) Foreign Application Priority Data
Aug. 16, 2023 (GB) 2312506.5

(51) Int. Cl. G01R 31/42

(52) U.S. Cl. CPC G01R 31/42

(57) ABSTRACT

A method of monitoring a three-phase alternating current (AC) signal includes carrying out analog to digital (A/D) conversion of each phase of the AC signal to produce respective digital voltage signals; calculating at least one of a direct component (d) value and a quadrature component (q) value in a rotating reference frame rotating at a fundamental frequency of the AC signal from the digital voltage signals using a Park Transform; comparing the at least one of a d value and a q value to one or more thresholds; and based on the result of the comparing, detecting deviation of the AC signal from a desired waveform.

### CROSS-REFERENCE TO RELATED APPLICATION AND PRIORITY CLAIM

This application claims priority under 35 U.S.C. § 119 to United Kingdom Patent Application No. 2312506.5 filed on Aug. 16, 2023, which is hereby incorporated by reference in its entirety.

### FIELD OF THE INVENTION

The present application relates to a method and system for AC fault detection, and in particular to a method and system for three-phase AC fault detection.

### BACKGROUND TO THE INVENTION

It is common for electrical equipment to be powered by an AC power supply having a sinusoidal voltage waveform. However, in practice, the waveform of the supplied power may deviate from the desired sinusoidal waveform, for example due to failure of the source of the power, damage to components and/or cables, or the sudden addition or removal of other loads from a power supply network. It is well known that such deviations from the desired sinusoidal waveform may prevent correct operation of the electrical equipment, requiring the AC power supply to be restored to the desired waveform so that the electrical equipment can return to correct operation.

There is a problem that some electrical equipment may be damaged by being provided with an AC power supply deviating from a desired sinusoidal waveform, and such damage may occur quickly. One example is in power electronics, where the power electronics can be quickly damaged by AC power supply deviating from a desired sinusoidal waveform. Accordingly, it is desirable to be able to quickly identify that an AC power supply is deviating from a desired sinusoidal waveform and disconnect electrical equipment from the deviating AC power supply in order to prevent, or minimize, damage.

Power protection devices, also known as monitoring relays, which identify that an AC power supply is deviating from a desired sinusoidal waveform and respond by opening the relay to disconnect and protect electrical equipment from the deviating AC power supply are known. However, known power protection devices typically have response times of around 100 milliseconds or more to identify a fault and disconnect. This response time is not quick enough to prevent damage to some types of electrical equipment. Accordingly, it is desirable to provide means to more quickly identify and respond to an AC power supply deviating from a desired sinusoidal waveform.

The inventors have devised the claimed invention in light of the above considerations. The embodiments described below are not limited to implementations which solve any or all of the disadvantages of the known approaches described above.

### SUMMARY OF INVENTION

This Summary is provided to introduce a selection of concepts in a simplified form that are further described below in the Detailed Description. This Summary is not intended to identify key features or essential features of the claimed subject matter; variants and alternative features which facilitate the working of the invention and/or serve to achieve a substantially similar technical effect should be considered as falling into the scope of the invention.

In a general sense, the present disclosure provides a method and system for monitoring a three-phase alternating current (AC) signal based on at least one of a direct component (d) value and a quadrature component (q) value produced using a Park Transform.

The invention is defined as set out in the appended set of claims.

In a first aspect of the present invention, there is provided a method of monitoring a three-phase alternating current (AC) signal, the method comprising: carrying out analog to digital (A/D) conversion of each phase of the AC signal to produce respective digital voltage signals; calculating at least one of a direct component (d) value and a quadrature component (q) value in a rotating reference frame rotating at a fundamental frequency of the AC signal from the digital voltage signals using a Park Transform; comparing the at least one of a d value and a q value to one or more thresholds; and based on the result of the comparing, detecting deviation of the AC signal from a desired waveform. This may provide the advantages of faster detection of deviation of the AC signal from a desired waveform.

In some embodiments, the calculating comprises applying a Decoupled Double Synchronous Reference Frame Phase Locked Loop (DDSRF PLL) algorithm to the digital voltage signals and obtaining the at least one of a d value and a q value from the output of a Park Transform of the DDSRF PLL algorithm. This may provide the advantage of reduced complexity and cost by allowing an existing DDSRF PLL to be used.

In some embodiments, the desired waveform is a predetermined sinusoidal waveform.

In some embodiments, the at least one of the d value and the q value is obtained from a positive sequence Park Transform of the DDSRF PLL algorithm.

In some embodiments, the at least one of the d value and the q value is the d value. This may provide the advantage of more accurate and reliable detection of deviation of the AC signal from a desired waveform.

In some embodiments, the comparing comprises determining whether the at least one of the d value and the q value is within a predetermined range by determining whether the at least one of the d value and the q value is between predetermined upper and lower threshold values. This may provide the advantage of more accurate and reliable detection of deviation of the AC signal from a desired waveform.

In some embodiments, deviation of the AC signal from a desired waveform is detected when the at least one of the d value and the q value is not within the predetermined range. This may provide the advantage of more accurate and reliable detection of deviation of the AC signal from a desired waveform.

In some embodiments, the method further comprising per unit (PU) scaling each digital voltage signal before applying the DDSRF PLL algorithm. This may provide the advantage of simplifying calculations.

In some embodiments, the method further comprising; obtaining at least one of a phase error value θ and an RMS voltage value V output by the DDSRF PLL algorithm, comparing the at least one of the phase error value and the RMS voltage value to one or more thresholds; and detecting deviation of the AC signal from a desired waveform further based on the result of this comparing. This may provide the advantage of more accurate and reliable detection of deviation of the AC signal from a desired waveform.

In a second aspect of the present invention, there is provided a method of protecting electrical equipment connected to a three-phase Alternating Current (AC) signal, the method comprising: carrying out analog to digital (A/D) conversion of each phase of the AC signal to produce respective digital voltage signals; calculating at least one of a direct component (d) value and a quadrature component (q) value in a rotating reference frame rotating at a fundamental frequency of the AC signal from the digital voltage signals using a Park Transform; comparing the at least one of a d value and a q value to one or more thresholds; based on the result of the comparing, detecting deviation of the AC signal from a desired waveform; and in response to detecting deviation from the desired waveform, disconnecting the electrical equipment from the AC signal. This may provide the advantages of faster detection of deviation of the AC signal from a desired waveform and disconnection of the electrical equipment.

In some embodiments, the calculating comprises applying a Decoupled Double Synchronous Reference Frame Phase Locked Loop (DDSRF PLL) algorithm to the digital voltage signals and obtaining the at least one of a d value and a q value from the output of a Park Transform of the DDSRF PLL algorithm. This may provide the advantage of reduced complexity and cost by allowing an existing DDSRF PLL to be used.

In a third aspect of the present invention, there is provided a system for monitoring a three-phase alternating current (AC) signal, the system comprising: at least one analog to digital (A/D) converter arranged to produce respective digital voltage signals corresponding to each phase of the AC signal; and processing means arranged to: calculate at least one of a direct component (d) value and a quadrature component (q) value in a rotating reference frame rotating at a fundamental frequency of the AC signal from the digital voltage signals using a Park Transform; compare the at least one of a d value and a q value to one or more thresholds; and based on the result of the comparing, detect deviation of the AC signal from a desired waveform. This may provide the advantages of faster detection of deviation of the AC signal from a desired waveform.

In some embodiments, the calculating comprises applying a Decoupled Double Synchronous Reference Frame Phase Locked Loop (DDSRF PLL) algorithm to the digital voltage signals and obtaining the at least one of a d value and a q value from the output of a Park Transform of the DDSRF PLL algorithm. This may provide the advantage of reduced complexity and cost by allowing an existing DDSRF PLL to be used.

In some embodiments, the desired waveform is a predetermined sinusoidal waveform.

In some embodiments, the at least one of the d value and the q value is obtained from a positive sequence Park Transform of the DDSRF PLL algorithm.

In some embodiments, the at least one of the d value and the q value is the d value. This may provide the advantage of more accurate and reliable detection of deviation of the AC signal from a desired waveform.

In some embodiments, the deviation of the AC signal from a desired waveform is detected when the at least one of the d value and the q value is not within the predetermined range. This may provide the advantage of more accurate and reliable detection of deviation of the AC signal from a desired waveform.

In some embodiments, the system further comprising means arranged to carry out per unit (PU) scaling of each digital voltage signal before applying the DDSRF PLL algorithm.

In some embodiments, the processor is further arranged to; obtain at least one of a phase error value θ and an RMS voltage value V output by the DDSRF PLL algorithm, compare the at least one of the phase error value and the RMS voltage value to one or more thresholds; and detect deviation of the AC signal from a desired waveform further based on the result of this comparing. This may provide the advantage of more accurate and reliable detection of deviation of the AC signal from a desired waveform.

In a fourth aspect of the present invention, there is provided a system for protecting electrical equipment connected to a three-phase Alternating Current (AC) signal, the system comprising: at least one analog to digital (A/D) converter arranged to produce respective digital voltage signals corresponding to each phase of the AC signal; processing means arranged to: calculate at least one of a direct component (d) value and a quadrature component (q) value in a rotating reference frame rotating at a fundamental frequency of the AC signal from the digital voltage signals using a Park Transform; compare the at least one of a d value and a q value to one or more thresholds; and based on the result of the comparing, detect deviation of the AC signal from a desired waveform; and further comprising a disconnection module arranged to disconnect the electrical equipment from the AC signal in response to the detection of deviation. This may provide the advantages of faster detection of deviation of the AC signal from a desired waveform and disconnection of the electrical equipment.

In some embodiments, the calculating comprises applying a Decoupled Double Synchronous Reference Frame Phase Locked Loop (DDSRF PLL) algorithm to the digital voltage signals and obtaining the at least one of a d value and a q value from the output of a Park Transform of the DDSRF PLL algorithm. This may provide the advantage of reduced complexity and cost by allowing an existing DDSRF PLL to be used.

The features and embodiments discussed above may be combined as appropriate, as would be apparent to a person skilled in the art, and may be combined with any of the aspects of the invention except where it is expressly provided that such a combination is not possible or the person skilled in the art would understand that such a combination is self-evidently not possible.

### BRIEF DESCRIPTION OF THE DRAWINGS

Embodiments of the present invention are described below, by way of example, with reference to the following drawings.

FIG. 1 shows a schematic diagram of an example of a power supply system according to an embodiment;

FIG. 2 shows a more detailed schematic diagram of a fault detection module used in the system of FIG. 1;

FIG. 3 is a flow chart of a method carried out by the fault detection module of FIG. 2;

FIG. 4 shows a more detailed schematic diagram of a feature extraction unit and a fault detection unit used in the fault detection module of FIG. 2;

FIGS. 5a to 5e show graphs of signals produced in a first example of operation of the fault detection module of FIG. 2;

FIGS. 6a to 6e show enlarged parts of the graphs of FIGS. 5a to 5e;

FIGS. 7a to 7e show further enlarged parts of the graphs of FIGS. 5a to 5e;

FIGS. 8a to 8e show graphs of signals produced in a second example of operation of the fault detection module of FIG. 2;

FIGS. 9a to 9e show enlarged parts of the graphs of FIGS. 8a to 8e;

FIGS. 10a to 10e show further enlarged parts of the graphs of FIGS. 8a to 5e; and

FIG. 11 shows graphs of signals produced in a third example of operation of the fault detection module shown in FIG. 2.

Common reference numerals are used throughout the figures to indicate the same or similar features.

### DETAILED DESCRIPTION

Embodiments of the present invention are described below by way of example only. These examples represent the best mode of putting the invention into practice that are currently known to the Applicant although they are not the only ways in which this could be achieved. the description sets forth the functions of the example and the sequence of steps for constructing and operating the example. However, the same or equivalent functions and sequences may be accomplished by different examples.

In broad terms, the general concept of the present disclosure is to use a Decoupled Double Synchronous Reference Frame Phase Locked Loop (DDSRF PLL) algorithm to process an AC signal, and to base a determination whether the AC signal is following a predetermined sinusoidal waveform on analysis of an internal d or q value produced by a Park Transform of the DDSRF PLL. This determination can then be used to trigger a response to deviation of the AC signal from the predetermined sinusoidal waveform, such as disconnection of the AC signal.

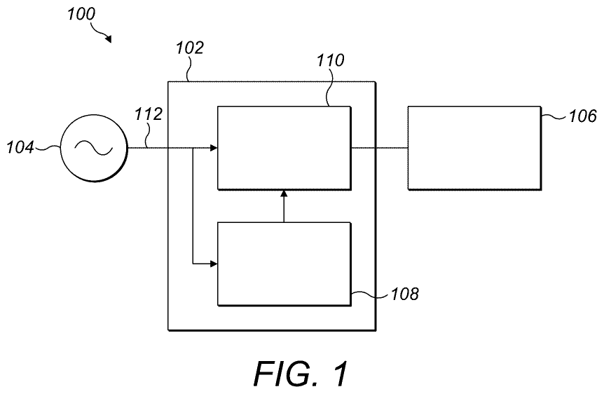

FIG. 1 shows a schematic diagram of a power supply system 100 comprising a fault detection and disconnection system 102 according to an embodiment. In the illustrated example of FIG. 1 the power supply system 100 comprises an AC power supply 104 connected to electrical equipment 106 by a power supply connection 112. In the illustrated example the electrical equipment 106 is power electronics. However, other types of electrical equipment 106 may be used in other examples.

In operation of the power supply system 100, the AC power supply 104 provides a three-phase AC power signal to the electrical equipment 106 through a power supply connection 112. Ideally, in correct operation, each phase of the AC power signal has a predetermined sinusoidal waveform with a predetermined frequency and voltage, with the waveforms of the three phases being 120° out of phase with each other. In FIG. 1 the power supply connection 112 is shown as a single connection for clarity, but it will be understood that the power supply connection 112 will typically comprise three physical conductive lines to carry respective phases of the three-phase AC power signal. In practice the power supply connection 112 may be more complex, for example a power supply network. In some examples the power supply connection 112 may be a power distribution network of a vehicle, such as a ship. In such examples the AC power supply 104 may be one or more turbo-generators and the electrical equipment 106 may be power electronics associated with electronics systems of the vehicle.

As shown in FIG. 1, the fault detection and disconnection system 102 comprises a fault detection module 108 and a disconnection module 110. As shown in FIG. 1, the fault detection module 108 is connected to the power supply connection 112 so that the fault detection module 108 can receive and monitor the three-phase AC power signal, and the disconnection module 110 is connected to the power supply connection 112 between the AC power supply 104 and the electrical equipment 106 so that the disconnection module 110 can selectively connect or disconnect the supply of AC power from the AC power supply 104 to the electrical equipment 106.

In operation of the fault detection and disconnection system 102, the fault detection module 108 monitors the three-phase AC power signal and determines whether a predetermined disconnection condition occurs. When disconnection condition occurs, the fault detection module 108 sends a disconnection instruction to the disconnection module 110. The disconnection module 110 is usually connected, allowing supply of the AC power signal through the power supply connection 112 to the electrical equipment 106, and responds to a disconnection instruction by disconnecting so that the AC power signal is not provided to the electrical equipment 106. The disconnection condition may comprise the AC power signal deviating from a desired sinusoidal waveform, such as changing in frequency, phase or RMS voltage. Such deviation of the AC power signal may, for example, be caused by equipment failure or damage to components of the AC power supply 104 and/or power supply connection 112, or equipment failure or damage to other electrical equipment connected to the power supply connection 112.

Accordingly, if the AC power signal through the power supply connection 112 deviates from a desired sinusoidal waveform, the fault detection and disconnection system 102 can disconnect the supply of the AC power supply signal to the electrical equipment 106 and so prevent, or reduce, possible damage to the electrical equipment 106 by the deviating AC power signal.

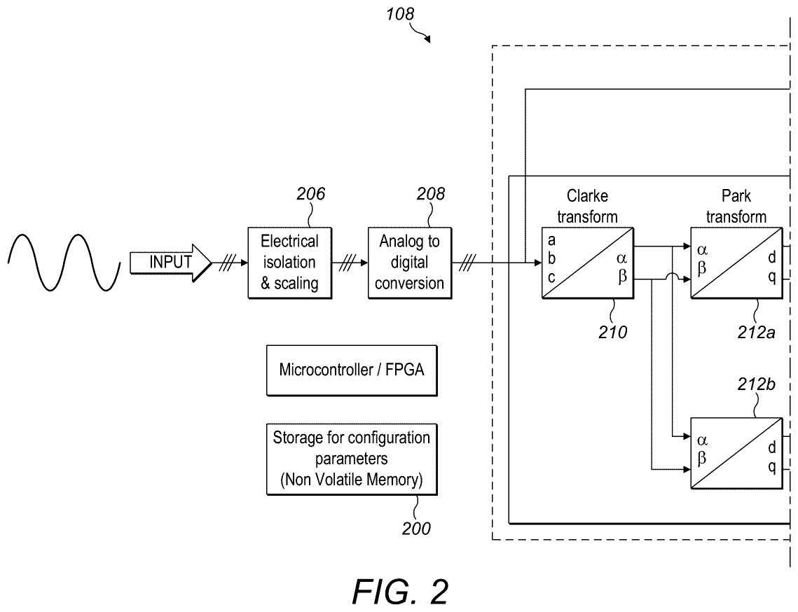

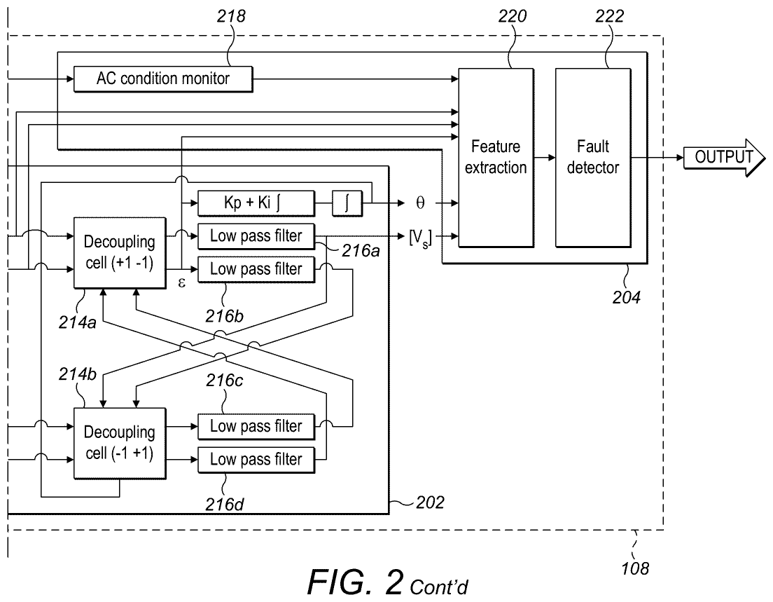

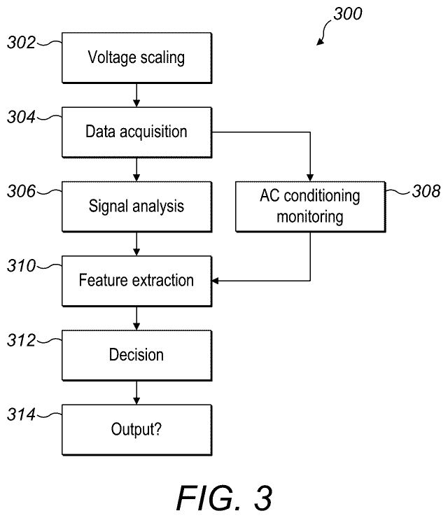

FIG. 2 shows a more detailed schematic diagram of the fault detection module 108 according to the embodiment of FIG. 1, while FIG. 3 shows a flow chart of a method 300 carried out by the fault detection module 108 in operation.

As shown in FIG. 2, the fault detection module 108 comprises an input section 200, a Decoupled Double Synchronous Reference Frame Phase Locked Loop (DDSRF PLL) section 202, and a monitoring section 204. In the illustrated embodiment the DDSRF PLL section 202 and the monitoring section 204 are implemented in software. In the illustrated example the fault detection module 108 is implemented in a microcontroller, for example a Texas Instruments C2000 Series microcontroller, with non-volatile memory storing configuration parameters of the fault detection module 108. However, the fault detection module 108 may be implemented in alternative ways in other examples. In some examples the fault detection module 108 may be implemented in a Field Programmable Gate Array (FPGA).

The input section 200 comprises an electrical isolation and voltage scaling unit 206 and an analog to digital conversion (ADC) unit 208. In operation, an initial voltage scaling block 302 of the method 300 is carried out by the electrical isolation and voltage scaling unit 206. In the initial voltage scaling block 302, the input section 200 receives the three-phase AC power supply signal from the power supply connection 112, and this is provided to the electrical isolation and voltage scaling unit 206 as an input. In the illustrated example this input is a three-phase AC power supply signal with an RMS voltage of 440V and a frequency of 60 Hz. In alternative examples different three-phase AC power supply signals having different parameters may be used, for example having a frequency in the range 60 Hz to 400 Hz. The electrical isolation and scaling unit 206 provides electrical isolation of the internal circuitry of the fault detection module 108 from the power supply connection 112, in order to prevent damage or interference to the fault detection module 108 from unintended signals on the power supply connection 112, such as noise or overvoltage. Further, the electrical isolation and voltage scaling unit 206 reduces the voltages of the three different phase signals of the input three-phase AC power supply signal by a predetermined scaling factor to produce three scaled down voltage signals corresponding to the three different phase signals. These scaled down voltage signals follow the relative changes in the respective voltage values of the three different phase signals over time and have scaled down voltage values within a safe low voltage range compatible with the digital electronics of the ADC unit 208. It will be understood that the three-phase AC power supply signal may be at a high voltage relative to the low voltages typically used in digital electronics. In the illustrated example the three-phase AC power supply signal has an RMS voltage of 440V, corresponding to a voltage range from −622V to +622V during each AC cycle, and this is scaled down to a voltage compatible with digital electronics by the electrical isolation and voltage scaling unit 206 in the voltage scaling block 302. In the illustrated example the analog to digital (A/D) converters of the ADC unit 208 can accept input voltages in the range 0V to +3.3V. Accordingly, in the illustrated example the electrical isolation and voltage scaling unit 206 attenuates and level shifts the high voltage input to match the voltage range of the A/D converters so that the positive peak voltage of the AC supply becomes equivalent to the A/D converter maximum input voltage of +3.3V, the zero voltage of the AC supply becomes equivalent to the A/D converter midpoint voltage of +1.65V, and the negative peak voltage of the AC supply becomes equivalent to the A/D converter minimum input voltage of 0V, The actual voltage span accommodated by the electrical isolation and voltage scaling unit 206 may be increased beyond that required by the nominal RMS value of the three-phase AC power supply signal to allow for variations in supply voltage due to noise and high and low line voltage tolerances. A number of different isolation circuits and voltage scaling circuits are known to the skilled person in this technical field, and a suitable isolation circuit and voltage scaling circuit may be selected as required in any specific implementation.

The electrical isolation and voltage scaling unit 206 provides the three scaled voltage signals derived from the respective three different phase signals of the input three-phase AC power supply signal to the ADC unit 208. It will be understood that the AC power supply signal and the three scaled voltage signals are analog voltage signals. In a data acquisition block 304 the ADC unit 208 carries out analog to digital (A/D) conversion of each of the three scaled analog voltage signals to produce three digital voltage signals, each comprising a respective time series of digital voltage values, and each representing a respective one of the three different phase signals of the input three-phase AC power supply signal. These three digital voltage signals corresponding to respective ones of the three different phase signals of the input three-phase AC power supply signal are referred to as the a, b and c phase voltage signals. The ADC unit 208 provides these a, b and c phase voltage signals to the DDSRF PLL section 202 and the monitoring section 204.

In the illustrated example, the ADC unit 208 comprises three separate A/D converters, with each A/D converter carrying out A/D conversion of one of the phase signals. The A/D converters operate at a sample rate of 150 kHz, for compatibility with the frequency range of the three-phase AC power supply signal of 60 Hz to 400 Hz, and compatibility with the electrical equipment 106. Different sample rates may be used in other examples, and these sample rates may be selected based on the expected frequency range of monitored signals in any specific implementation.

In the illustrated example the digital values output by the ADC unit 208 are per unit (PU) scaled before being output to other parts of the system 100. These PU scaled values are expressed as a fraction of an associated nominal input value to simplify subsequent calculations, i.e., Vₚᵤ=V_{measured}÷Vₙₒₘᵢₙₐₗ. Thus, in the illustrated example where the three-phase AC power supply signal has a nominal (that is, intended) RMS value of 440V, corresponding to a nominal peak voltage of 622V, the PU voltage values are calculated as Vₚᵤ=V_{measured}÷622, so that a value of 600V would be expressed as a PU value Vₚᵤ=600÷622=0.964. The use of PU scaled values is not essential, but may simplify calculations performed by the DDSRF PLL section 202 and the monitoring section 204.

In a signal analysis block 306 the DDSRF PLL section 202 uses a DDSRF PLL algorithm to determine voltage and phase angle values of the three-phase AC power supply signal from the a, b and c phase digital voltage signals provided by the ADC unit 208 of the input section 200. In the illustrated embodiment the DDSRF PLL section 202 is implemented in software, so that the various parts of the DDSRF PLL section 202 described below are functional software elements, such as modules.

The DDSRF PLL algorithm is well known, and was first described in “Decoupled Double Synchronous Reference Frame PLL for Power Converters Control”. P Rodriguez, J Pou, J Bergas, J I Candela, R P Burgos, D Boroyevitch. IEEE Transactions on Power Electronics, Vol 22, No. 2, March 2007, and “Correction to “Decoupled Double Synchronous Reference Frame PLL for Power Converters Control” ”. P Rodriguez, J Pou, J Bergas, J I Candela, R P Burgos, D Boroyevitch. IEEE Transactions on Power Electronics, Vol 22, No. 3, May 2007. The DDSRF PLL algorithm uses three-phase Clarke and Park transforms and a phase-locked loop to process digital voltage signals of the three different phases of a three-phase AC signal to produce estimates of the phase angle and voltage of the three-phase AC signal. DDSRF PLL algorithms are commonly used for synchronizing three-phase power converters, by using the estimated phase angle to determine the points in time when solid state switching components of the power converters should be switched on and off to correctly rectify and regulate the output power delivered by the power converter.

As shown in FIG. 2, the DDSRF PLL section 202 comprises a Clarke transform element 210, two Park transform elements 212a and 212b, two decoupling cells 214a and 214b, and four low pass filters 216a to 216d. As is explained above, the DDSRF PLL algorithm and its component parts are well known, and accordingly it is not necessary to describe these in detail herein.

To carry out the DDSRF PLL algorithm, the Clarke transform element 210 is arranged to convert the a, b and c phase digital voltage signals received from the input section 200 into αβ values, corresponding to a translation of the a, b and c phase digital voltage signals in an abc natural rotating reference frame into α, β values in an αβ-stationary reference frame. The αβ values output by the Clarke Transform element 210 are then provided as inputs to a positive sequence Park Transform element 212a and a negative sequence Park transform element 212b. The Park Transform is a mathematical transformation which maps sinusoidal signals to equivalent DC ‘d, q, 0’ parameters to allow complex sinusoidal signal relationships to be analyzed in a relatively simple manner. Each Park transform element 212a and 212b converts the αβ values received from the Clarke transform element 210 into dq values, corresponding to the translation of the αβ values in the αβ-stationary reference frame into dq values in a rotating synchronous reference frame, with the positive sequence Park transform element 212a and a negative sequence Park transform element 212b corresponding to reference frames rotating in opposite directions. The d value is a direct component and the q value is a quadrature component. The dq values from the positive sequence and negative sequence Park transform elements 212a and 212b are provided to respective decoupling cells 214a and 214b and input into a phase-locked loop formed by the decoupling cells 214a and 214b and the four low pass filters 216a to 216d.

The DDSRF PLL section 202 then uses the phase locked loop of the DDSRF PLL algorithm to produce as outputs a phase error value θ of the input three-phase AC power supply signal and an RMS voltage value Vs of the input three-phase AC power supply signal. The operation of the DDSRF PLL algorithm to produce and output a phase error value and a voltage value in this way is well known and does not need to be described in detail herein.

The DDSRF PLL section 202 also provides the d value and the q value output by the positive sequence Park transform element 212a as outputs. This differs from a conventional DDSRF PLL algorithm, which only uses the d and q values internally within the DDSRF PLL algorithm itself, and provides only the phase error value θ and the voltage value Vs as outputs.

The illustrated embodiment provides the d value and the q value output by the positive sequence Park transform element 212a as outputs. This is not essential, and the d value and the q value output by the negative sequence Park transform element 212b could alternatively, or additionally, be provided as outputs.

The d value, the q value, the phase error value θ, and the RMS voltage value Vs output by the DDSRF PLL section 202 are provided to the monitoring section 204. The d and q parameters provide two orthogonal values which characterize the state of the three-phase AC supply voltage at a particular point in time. In the illustrated embodiments, the d value may be regarded as representing the peak input voltage, and the q value may be regarded as representing phase imbalance. In the illustrated example, the d value will be Per Unit (PU) scaled because they are derived from the PU scaled digital voltage values output by the ADC unit 208, but as is explained above, the use of PU scaling is not essential. In the present invention, the d value of voltage will generally dominate because the value of q will be at, or close to, zero when the three different phase voltages of the three-phase AC supply voltage is balanced and fault free. As a result, without wishing to be bound by theory, it is expected that it will be easier to detect changes in the d value than changes in the q value in most situations, so that monitoring and fault detection based on the d value will be more effective and provide a quicker response than monitoring and fault detection based on the q value.

The monitoring section 204 comprises an AC condition monitor 218, a feature extraction module 220, and a fault detection module 222. In summary, as will be explained in more detail below, the monitoring section 204 uses the d value output by the DDSRF PLL section 202 to detect deviation of the three-phase AC power signal from a desired sinusoidal waveform and make an appropriate response.

The use of the d value by the monitoring section 204 is not essential, and in alternative examples the monitoring section 204 may use the q value, or both the d value and the q value in combination, to detect deviation of the three-phase AC power signal from a desired sinusoidal waveform and make an appropriate response. However, as is explained above, in practice the response of the d value to deviation of the three-phase AC power signal will generally be greater than that of the q value, so that changes in the d value will tend to dominate the response of the q value. As a result, it is expected that monitoring and fault detection based on the d value may be more effective and provide a quicker response than monitoring and fault detection based on the q value.

Optionally, the monitoring section 204 may also use other signals in combination with the d value and/or q value to detect deviation of the three-phase AC power signal from a desired sinusoidal waveform. As will be explained below, the use of the d or q value may enable deviation of the three-phase AC power signal from a desired sinusoidal waveform to be detected and responded to more quickly than currently known approaches. In the illustrated embodiment the monitoring section 204 is implemented in software, so that the various parts of the monitoring section 204 described below are functional software elements, such as modules.

The d value and the q value output by a Park transform element 212 change in response to deviation of the three-phase AC power signal from a desired sinusoidal waveform more quickly than other outputs of the DDSRF PLL section 202, and in particular, more quickly than the phase error value θ and the RMS voltage value Vs conventionally provided as outputs by a DDSRF PLL algorithm. Accordingly, the use of the d value and/or the q value may allow deviation to be detected more quickly than conventional methods.

In an AC condition monitoring block 308 the AC condition monitor 218 analyses the digital values output by the ADC unit 208 in parallel with the processing by the DDSRF PLL section 202 in the signal analysis block 306. The AC condition monitor 218 uses the digital values to produce measurements of parameters including the frequency and RMS voltages, and the direction of phase rotation of the three-phase AC power signal. The AC condition monitor 218 also uses the digital values to produce a confirmation of phase presence of the three phases of the three-phase AC power signal and a Fast Fourier Transform (FFT) of the three-phase AC power signal waveform. The AC condition monitor 218 then outputs these measured parameter values to the feature extraction module 220. Typically, the AC condition monitor 218 will accrue the digital values across one or more consecutive sinusoidal cycles of the three-phase AC power signal before updating its output of the measured parameters. This introduces a delay before changes in voltage or frequency can be detected, for example, 16.6 milliseconds for a 60 Hz Ac signal, or 2.5 milliseconds for a 400 Hz AC signal. The AC condition monitor may use any known method to produce these measured parameter values from the digital values. A number of suitable methods are known.

In some examples the AC Condition Monitor accrues ADC digital voltage samples at a pre-determined & constant sample rate. The accrued time series data is then analyzed using the time domain or frequency domain methods outlined below. These time domain or frequency domain methods are well known to the skilled person in this technical field, and do not need to be described in detail herein. By using known time domain methods: Phase presence for each of the three input voltages may be determined by comparing the digital voltage values associated with adjacent samples, counting how many samples it takes to switch from positive to negative & back again (zero crossing), or counting how many samples it takes to reach adjacent minima and maxima as the AC signal oscillates within each cycle; Phase rotation may be determined by tracking the order in which the digital phase voltages ascend (or descend) from a chosen reference phase; Frequency may be estimated by calculating the reciprocal of the elapsed time between zero crossings, minima, or maxima; Peak voltage may be estimated from the minima & maxima values; RMS voltage may be estimated by assuming the waveform is sinusoidal and calculated the root mean square of the average peak voltage value (If required, non-sinusoidal waveforms may be catered for by using a Fast Fourier Transform (FFT) to determine the harmonic content to infer the shape of the waveform, then applying a suitable correction term). By using known frequency domain methods, Frequency & waveform distortion may be estimated by decomposing the accrued time series digital voltage samples into fundamental & higher order frequency components by a suitable algorithm such as Fast Fourier Transform (FFT), Goertzel or Discrete Wavelet Transform. It will be understood that these methods are sensitive to noise and errors present in the digital voltage values being processed so that additional filtering will be required to interpolate and/or reject bad samples. These filtering requirements are well known to the skilled person and need not be described in detail herein.

Without wishing to be bound by theory, it is expected that changes in the d value and/or q value output by the DDSRF PLL section 202 will indicate deviation of the three-phase AC power signal from a desired sinusoidal waveform far more quickly (that is, with less delay) than this will be indicated by changes in the parameter values output by the AC condition monitor 218. Further, as is explained above, it is expected that changes in the d value will indicate deviation more quickly than this will be indicated by changes in the q value. However, the parameter values provided by the AC condition monitor 218 may still be useful in some circumstances in determining whether the condition of the three-phase AC power signal is acceptable for use. Further, the independently generated parameter values provided by the AC condition monitor 218, although produced with a greater delay, may provide a useful backup or ‘sanity check’ to confirm proper operation of the DDSRF PLL section 202.

In a feature extraction block 310, the feature extraction unit 220 compares the d value received from the DDSRF PLL section 202 to one or more predetermined thresholds and outputs the result of the comparison to the fault detection module 222. In the illustrated example, the feature extraction unit 220 may determine whether the received d value is within a predetermined range having predetermined upper and lower threshold values by comparing the received d value to the predetermined upper and lower threshold values and generating an output indicating that the d value is within the predetermined range when it is between or equal to the upper and lower threshold values, or indicating that it is outside the predetermined range when it is not between or equal to the upper and lower threshold values. The feature extraction unit preferably includes hysteresis to eliminate jitter where the value is close to a threshold, to avoid the value being repeatedly determined to be inside and outside the predetermined range on consecutive determinations.

In the illustrated example the feature extraction unit 220 also compares other values received from the DDSRF PLL section 202 and the AC condition monitor 218 in addition to the d value to respective predetermined thresholds and outputs the results of these comparisons to the fault detection unit 222. However, this is not essential, and the d value only may be used. In particular, in the illustrated example the feature extraction unit 220 also compares the q values received from the DDSRF PLL section 202 in addition to the d value to respective predetermined thresholds and outputs the results of these comparisons to the fault detection unit 222. The use of these additional values by the fault detection unit 222, and in particular the use of the q value, is optional and not essential, but may provide an improved ability to reliably detect and respond to different problems with the AC power supply based on combinations of comparisons of different parameters to respective thresholds.

In the feature extraction block 310 the feature extraction unit 220 optionally also compares the q value, the phase error value θ and the RMS voltage value Vs received from the DDSRF PLL section 202 to one or more respective predetermined thresholds, and optionally compares the frequency, RMS voltage, indication of phase presence, and FFT provided by the AC condition monitor 218 to one or more respective predetermined thresholds. The feature extraction unit 220 outputs the results of these optional comparisons to the fault detection unit 222. For example, the feature extraction unit 220 may determine whether each of the received q value, phase error value θ, and RMS voltage values is within a predetermined range having predetermined upper and lower threshold values by comparing each received value to respective predetermined upper and lower threshold values and generating an output indicating that the value is within the predetermined range when it is between or equal to the upper and lower threshold values, or indicating that it is outside the predetermined range when it is not between or equal to the upper and lower threshold values. Further, the feature extraction unit 220 may output a confirmation that all phases are present, or not, based on the received indication of phase presence, and may compare the received FFT to one or more thresholds and provide an output based on the result of the comparison.

In a decision block 312, the fault detection unit 222 uses the comparison result(s) received from the feature extraction unit 220 to make a determination whether a disconnection condition has occurred. This may be done by determining whether the status of the three-phase AC power signal waveform is a normal status where the AC power signal is following the predetermined sinusoidal waveform sufficiently closely that the quality of the three-phase AC power signal waveform is acceptable, or whether the status of the three-phase AC power signal waveform is a fault status where the AC power signal is not following the predetermined sinusoidal waveform sufficiently closely so that the quality of the three-phase AC power signal waveform is not acceptable. If the fault detection unit 222 determines a fault status, this is a disconnection condition, and the fault detection unit 222 outputs a fault signal to the disconnection module 110 in an output block 314. The fault signal may, for example be sent via a dedicated General Purpose Input Output (GPIO) pin and/or a software register interface, as desired in any specific implementation.

On receipt of the fault signal from the fault detection unit 222, the disconnection module 110 disconnects the electrical equipment 106 from the power supply connection 112 so that the three-phase AC power signal is not provided to the electrical equipment 106, so preventing, or minimizing, damage to the electrical equipment 106 from the faulty three-phase AC power signal which is not correctly following the predetermined sinusoidal waveform.

Deviation of the three-phase AC power signal from a desired sinusoidal waveform can be detected more quickly based upon the d value alone, or on the q value or the d value and the q value in combination, than by other methods. In particular, more quickly than detection based on the phase error value or RMS voltage value output by the DDSRF PLL algorithm or the outputs of the AC condition monitor 218. Accordingly, by basing the disconnection decision on the d value and/or q value, at least in part, deviation of the three-phase AC power signal from a desired sinusoidal waveform can be detected and responded to more quickly by disconnecting the electrical equipment 106 from the three-phase AC power signal, which may prevent, or reduce, damage which would otherwise be caused to the electrical equipment by the faulty three-phase AC power signal.

In the illustrated embodiment the fault detection unit 222 primarily uses the d value to identify deviation of the three-phase AC power signal from a desired sinusoidal waveform. Without wishing to be bound by theory, it is expected that the d and q values will provide similar speed of reaction to a change in the AC power signal, but that the response of the d value will generally be larger than that of the q value, so that the use of the d value may be preferred.

In the illustrated embodiment deviation of the three-phase AC power signal from a desired sinusoidal waveform can be detected based on the d and/or q value and responded to by disconnecting the electrical equipment 106 from the three-phase AC power signal in around 100 microseconds, even in harsh electrical environments, much more quickly than in conventional systems, which typically have fault detection and disconnection times of around 100 milliseconds.

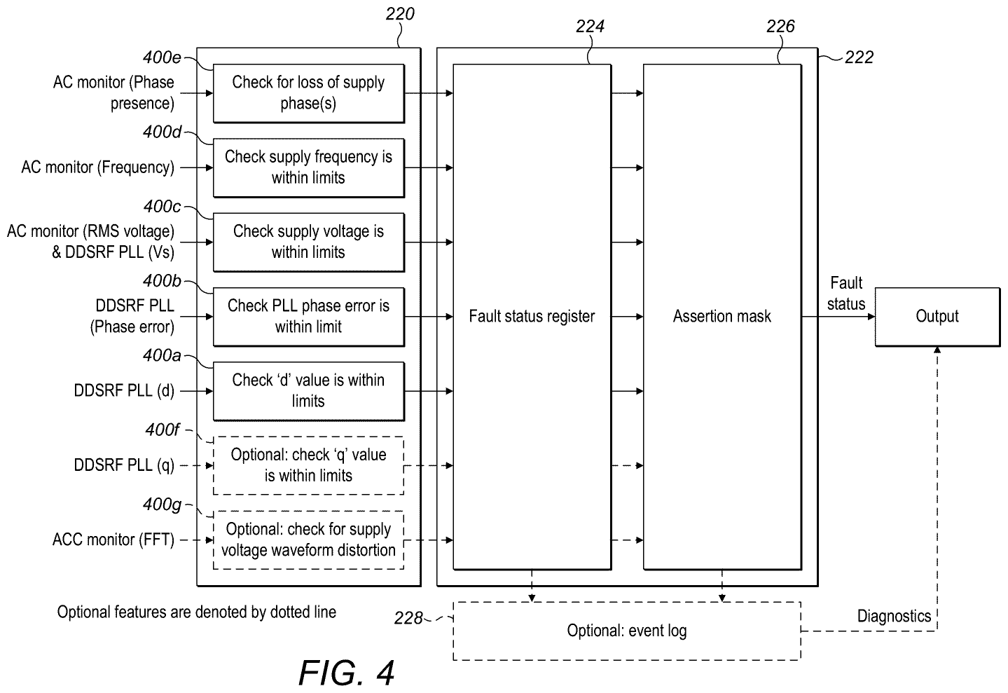

FIG. 4 shows a more detailed schematic diagram of the feature extraction unit 220 and the fault detection unit 222. As shown in FIG. 4, the feature extraction unit 220 comprises a plurality of check elements 400a to 400g. Each check element 400 receives values of a specific parameter, compares the received values to a respective predetermined range or limits, and generates as an output a message indicating the result of the comparison.

In the example of FIG. 4, the check element 400a receives d values from the DDSRF PLL section 202, compares the received values to predetermined limits or thresholds to confirm whether or not the d values are within these limits, and generates a message indicating the result of the comparison. Similarly, the check element 400b receives values of the phase error value θ from the DDSRF PLL section 202, compares the received values to predetermined limits or thresholds to confirm whether or not the phase error values are within these limits, and generates a message indicating the result of the comparison. The check element 400c receives values of the RMS voltage from both the DDSRF PLL section 202 and the AC condition monitor 218, compares the received values to predetermined limits or thresholds to confirm whether or not the RMS voltage values are within these limits, and generates a message indicating the result of the comparison. The check element 400d receives values of the frequency from the AC condition monitor 218, compares the received values to predetermined limits or thresholds to confirm whether or not the frequency values are within these limits, and generates a message indicating the result of the comparison. The check element 400e receives indications of phase presence from the AC condition monitor 218, confirms whether or not all three phases are present, and generates a message indicating the result of the comparison. The check element 400f receives q values from the DDSRF PLL section 202, compares the received values to predetermined limits or thresholds to confirm whether or not the q values are within these limits, and generates a message indicating the result of the comparison. The check element 400g receives FFT values from the AC condition monitor 218, compares the received values to predetermined limits or thresholds to confirm whether or not the FFT values are acceptable, and generates a message indicating the result of the comparison.

The fault detection unit 222 comprises a status register 224 and an assertion mask 226. The fault detection unit 222 stores messages received from the different check elements 400a-g of the feature extraction unit 220 in the status register 224, so that at any time the status register 224 contains the most recently received message from each of the check elements 400a-g. The assertion mask 226 defines how combinations of different messages from the check elements 400a-g regarding the status of the corresponding parameter values are to be regarded as indicating that the quality of the three-phase AC power signal waveform is acceptable, so that there is no disconnection condition, or unacceptable, so that there is a disconnection condition. Each time a new message is received from a check element 400a-g, or alternatively, periodically, the assertion mask 226 checks whether the current combination of stored messages indicates a disconnection condition. If the check indicates a disconnection condition, the assertion mask 226 outputs a fault signal to the disconnection module 110.

The assertion mask 226 may define combinations of different messages in as much complexity as desired or appropriate in any specific implementation. For example, the assertion mask 226 may define the d value message from the check element 400a indicating that the d value is outside the predetermined limits as indicating that the quality of the three-phase AC power signal waveform is unacceptable, so that there is a disconnection condition. In some examples, the assertion mask 226 may also define specific combinations of different messages from the different check elements 400a-g regarding the status of the corresponding parameter values are to be regarded as indicating that the quality of the three-phase AC power signal waveform is unacceptable, so that there is a disconnection condition. The assertion mask 226 combines the results of the comparisons of the different measured parameters to respective thresholds into an aggregate acceptable/unacceptable decision. The thresholds and the manner in which the different results are combined may be user programmable as required in any specific implementation based on fault severity and operating mode parameters, and stored in non-volatile memory. This approach may allow the response of the fault detection unit to be tuned and optimized for any given situation.

Optionally, the fault detection module 108 may further comprise an event log 228. The event log 228 may be used to keep a record of disconnection events and associated information.

In other examples, the fault detection module 108 may be arranged to measure and respond to further parameters in addition to those in the illustrated embodiment. In some examples, the input section 200 may be further arranged to sense input current so that the fault detection module 108 can determine further parameters such as current, energy use and power factor, which can be used for monitoring and fault detection of the AC signal.

In some examples, in addition to outputting a fault signal in response to identification of a fault condition, the fault detection module 108 may further provide real time diagnostic information about the status of some or all of the monitored parameters, for example via supplementary GPIO output pins and/or via digital to analog converters (DAC) for time varying data. In some examples, this diagnostic information could be provided to a timestamped event recorder.

In the illustrated embodiment, a Park Transform of a Decoupled Double Synchronous Reference Frame Phase Locked Loop (DDSRF PLL) algorithm is used to provide the d and/or q values. The use of a DDSRF PLL algorithm is not essential, although it may be advantageous to use the present invention in situations where a DDSRF PLL is already present or intended to be used. In alternative examples a Park Transform may be used to produce the d and/or q values without the Park transform being incorporated in a DDSRF PLL algorithm. For example, in the example of FIG. 3, the Clarke Transform element 210 and the positive Park transform 212a only could be used, with the negative Park transform 212b, the decoupling cells 214a and 214b, and the four low pass filters 216a to 216d being omitted. In other alternative examples the negative Park transform 212b could be used instead of the positive Park transform 212a.

In the illustrated embodiment, a Clarke transform is used to convert the a, b and c phase digital voltage signals received from the input section 200 into αβ values, corresponding to a translation of the a, b and c phase digital voltage signals in an abc natural rotating reference frame into α, β values in an αβ-stationary reference frame. This is not essential, and other methods of carrying out this translation may be used.

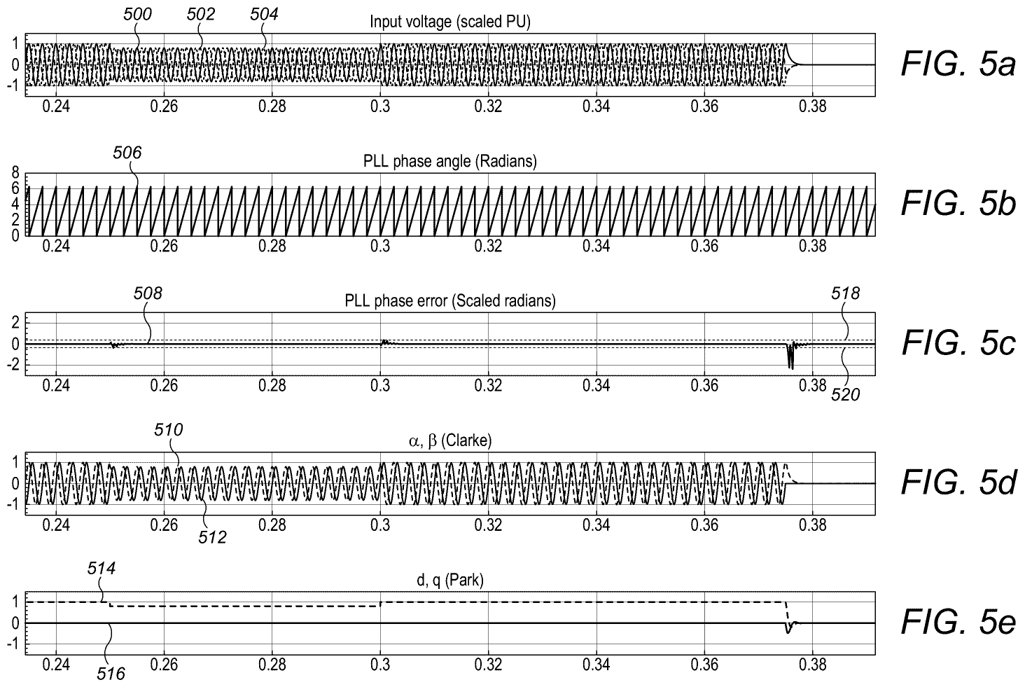

FIGS. 5a to 5e are graphs showing a first example of simulation results of operation of the fault detection module 108 where an idealized three-phase AC signal (that is, a three-phase AC signal without noise or distortion) at a frequency of 400 Hz and starting with a steady state nominal PU scaled voltage of value 1 has the voltage suddenly drop by 20% to 0.8 at a time t=0.25, followed by a sudden rise back to a value of 1 at time t=0.3, before turning off with an exponential decay (to simulate a complete loss of input power) at a time t=0.375.

FIG. 5a shows the PU scaled three-phase supply voltage supplied to the fault detection and disconnection system 102, where the red line 500 indicates the phase A voltage (Vₐ), the blue line 502 represents the phase B voltage (V_{b}), and the green line 504 represents the phase C voltage (V_{c}).

FIG. 5b shows the instantaneous predicted phase angle calculated by the DDSRF PLL algorithm of the DDSRF PLL section 202. The sawtooth shape is due to the regular periodic nature of the input signals. In FIG. 5b the line 506 represents the Phase angle (θ). FIG. 5b shows each individual AC cycle transiting from 0 to 2 pi radians in 2.5 milliseconds (i.e., 1/400 Hz) before repeating.

FIG. 5c shows the phase error calculated by the DDSRF PLL algorithm of the DDSRF PLL section 202. The line 508 represents the phase error (F), the difference between the actual input three-phase AC signal and the phase angle predicted by the DDSRF PLL algorithm. Note that phase angle data continues to be generated after the loss of input power event because of a frequency feed-forward term and damping effects of the control loop associated with the DDSRF PLL algorithm.

FIG. 5d shows the 2-phase stationary reference frame values calculated by the internal Clarke transformation 210 of the DDSRF PLL section 202, where the blue line 510 represents the α value and the red line 512 represents the 3 value.

FIG. 5e shows the direct and quadrature DC values d and q calculated by the internal positive sequence Park transformation 212a of the DDSRF PLL section 202, where the blue line 514 represents the d value and the red line 516 represents the q value.

As can be seen from FIGS. 5a to 5e, the phase angle of FIG. 5b accurately tracks the input voltage of FIG. 5a. The phase error of FIG. 5c has small perturbations which are aligned to the step changes in input voltage in FIG. 5a at t=0.25 & t=0.3, and a large perturbation at t=0.375 which is aligned to the loss of input power event when the voltage is removed. The upper and lower limit lines 518 and 520 in FIG. 5c error plot indicate the phase error threshold. This value of phase error threshold was chosen to let the system ride through the 20% voltage drop and rise events without triggering a disconnection condition. Perturbations that exceed this threshold will trigger a disconnection condition. This can be seen at t=0.375 where the loss of input power causes the phase error 508 to drop below the lower limit line 520.

As can be seen by comparing FIGS. 5a and 5e, the changes in the Park transform ‘d’ value 514 (which represents the PU scaled peak input voltage) are aligned closely in time to the changes in input voltage in FIG. 5a at t=0.25, t=0.3 & t=0.375. There are also changes in the Park transform ‘q’ value 516 aligned closely in time to the changes in input voltage in FIG. 5a at t=0.25, t=0.3 & t=0.375, but these changes in the ‘q’ value are too small to be visible in FIG. 5e, likely because the input voltages are perfectly balanced. However, as can be seen in FIG. 5e, the changes in the ‘d’ value 514 are clearly visible. Accordingly, it can be seen that the changes in the ‘d’ value may be larger than the changes in the ‘q’ value 516, and so easier to detect, and can be more accurately compared to thresholds. Accordingly, it is expected that the Park transform ‘d’ value will be more useful as a means of determining that the AC input power deviates from a desired sinusoidal waveform than the Park transform ‘q’ value. However, the Park transform ‘q’ value could still be used as an alternative to, or in addition to, the Park transform ‘d’ value.

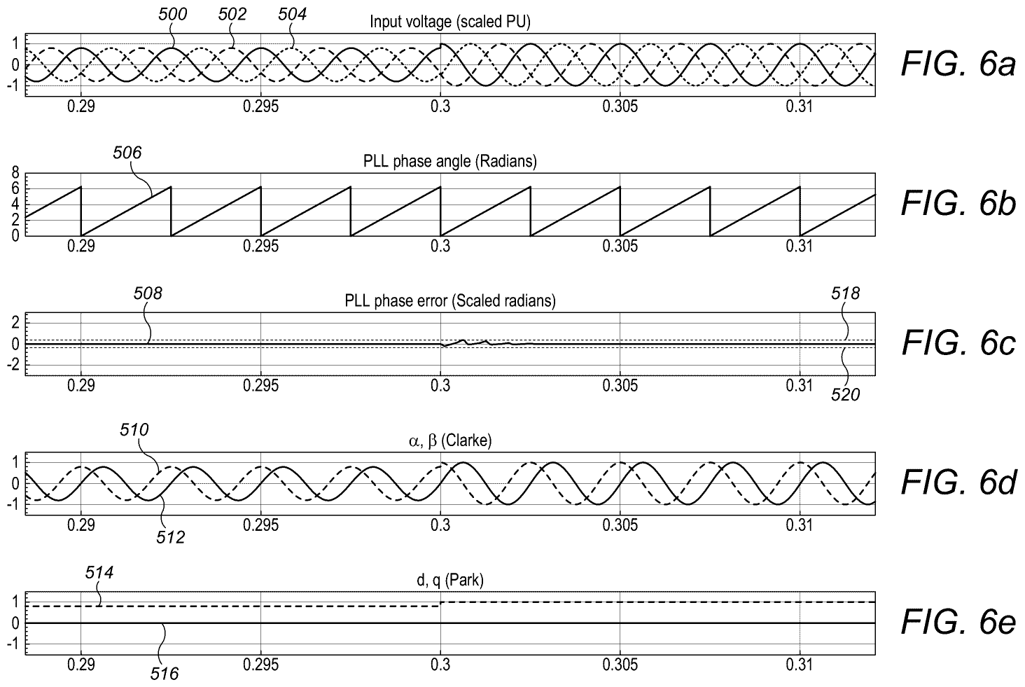

FIGS. 6a to 6e show enlargements of sections of the graphs of FIGS. 5a to 5e respectively, showing the section around t=0.3 when the voltage rise occurs. As can be seen more clearly by comparing FIGS. 6a and 6e, the changes in the Park transform ‘d’ value 514 (which represents the PU scaled peak input voltage) are aligned closely in time to the change in input voltage in FIG. 6a at t=0.3. Similarly to FIG. 5e, the changes in the ‘q’ value are too small to be visible in FIG. 6e.

FIGS. 7a to 7e show enlargements of sections of the graphs of FIGS. 5a to 5e respectively, showing the section around t=0.375 when the loss of input power occurs. As can be seen more clearly by comparing FIGS. 7a and 7e, the change in the Park transform ‘d’ value 514 (which represents the PU scaled peak input voltage) is aligned closely in time to the loss of input power of the input voltage in FIG. 7a at t=0.375. Further, by comparing with FIG. 7c it can be seen that the change in the Park transform ‘d’ value 514 drops faster than the phase error 508 of FIG. 7c, and so will detect the loss of input power and trigger a disconnection more quickly in response to the loss of input power when an associated error threshold 700 is crossed at time 702 than will be done by the phase error 508 passing the lower limit line 520 at time 704. Further, the change in the Park transform ‘q’ value 516 also aligned closely in time to the loss of input power of the input voltage in FIG. 7a at t=0.375, and it can be seen that the change in the Park transform ‘q’ value 516 drops faster than the phase error 508 of FIG. 7c, and so will detect the loss of input power and trigger a disconnection more quickly in response to the loss of input power than will be done based on the phase error 508.

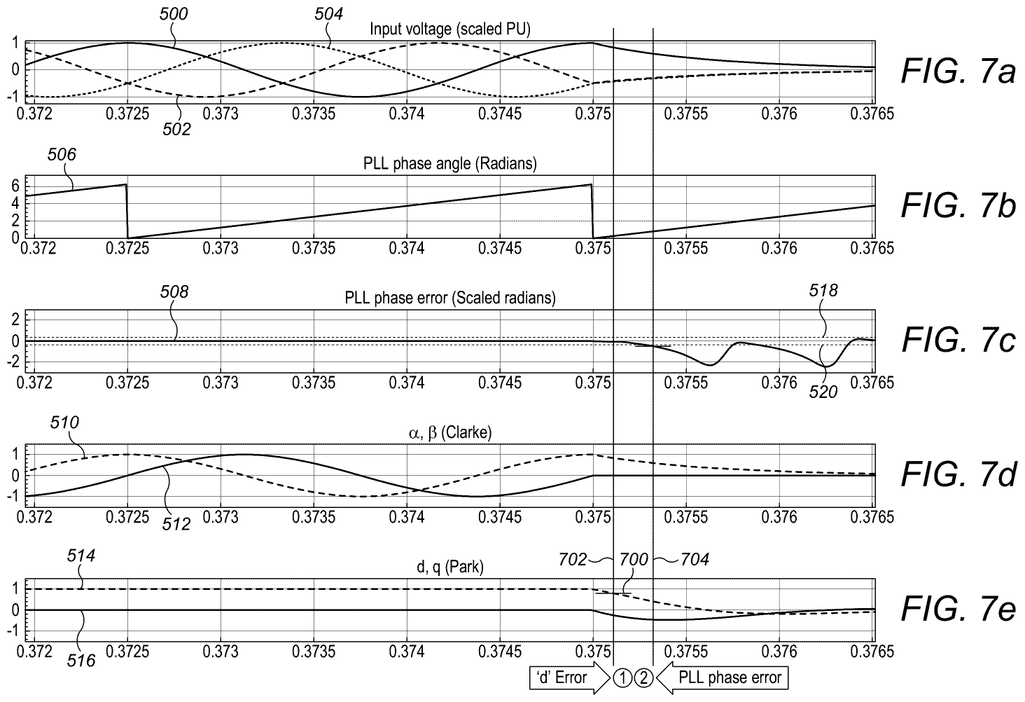

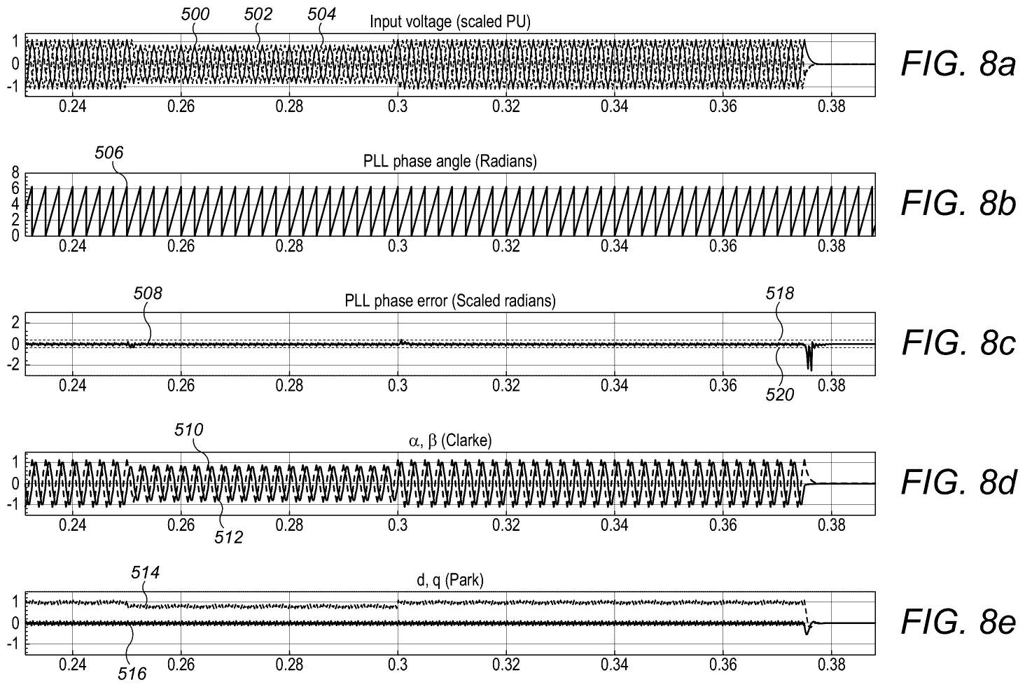

FIGS. 8a to 8e are graphs showing a second example of simulation results of operation of the fault detection module 108 where a three-phase AC signal including distortion, at a frequency of 400 Hz, and starting with a steady state nominal PU scaled voltage of value 1 has the voltage suddenly drop by 20% to 0.8 at a time t=0.25, followed by a sudden rise back to a value of 1 at time t=0.3, before turning off with an exponential decay (to simulate a complete loss of input power) at a time t=0.375. FIGS. 8a to 8e of the second example correspond to FIGS. 5a to 5e of the first example, but with additional frequency harmonics added to the input. This type of harmonic noise is common in AC monitoring and presents an additional challenge of preventing the harmonic noise triggering spurious fault detection, possibly leading to unnecessary and undesirable spurious disconnection.

FIG. 8a shows the PU scaled three-phase supply voltage supplied to the fault detection and disconnection system 102, where the red line 500 indicates the phase A voltage (Vₐ), the blue line 502 represents the phase B voltage (V_{b}), and the green line 504 represents the phase C voltage (V_{c}). Harmonic noise is visible in lines 500, 502 and 504 in FIG. 8a.

FIG. 8b shows the instantaneous predicted phase angle calculated by the DDSRF PLL algorithm of the DDSRF PLL section 202. It can be seen in FIG. 8b that the Phase angle (0) represented by line 506 accurately tracks the input voltage regardless of the harmonic noise.

FIG. 8c shows the phase error calculated by the DDSRF PLL algorithm of the DDSRF PLL section 202. It can be seen in FIG. 8c that the perturbations in the phase error (F) remain aligned with the step changes in the input voltage, although these perturbations are now superimposed on the background harmonic noise. Further, it can be seen that even with the harmonic noise the upper and lower limit lines 518 and 520 of the phase error threshold are not exceeded by the 20% voltage drop and rise events, so that these do not trigger a disconnection condition, and a disconnection condition would only be triggered by the phase error threshold being exceeded in response to the loss of input power.

FIG. 8d shows the 2-phase stationary reference frame values calculated by the internal Clarke transformation 210 of the DDSRF PLL section 202, where the blue line 510 represents the α value and the red line 512 represents the R value.

FIG. 8e shows the direct and quadrature DC values d and q calculated by the internal positive sequence Park transformation 212a of the DDSRF PLL section 202, where the blue line 514 represents the d value and the red line 516 represents the q value. As can be seen in FIG. 8e, the changes in the d value and the q value remain aligned in time with the step changes in the input voltage even with the background harmonic noise. As can be seen in FIG. 8e, the changes in the ‘d’ value 514 are larger than the changes in the ‘q’ value 516. In contrast to FIG. 5e, the changes in the ‘q’ value 516 is visible in FIG. 8e, this is because the input voltage is distorted by harmonic noise, creating small phase imbalances which are revealed by q.

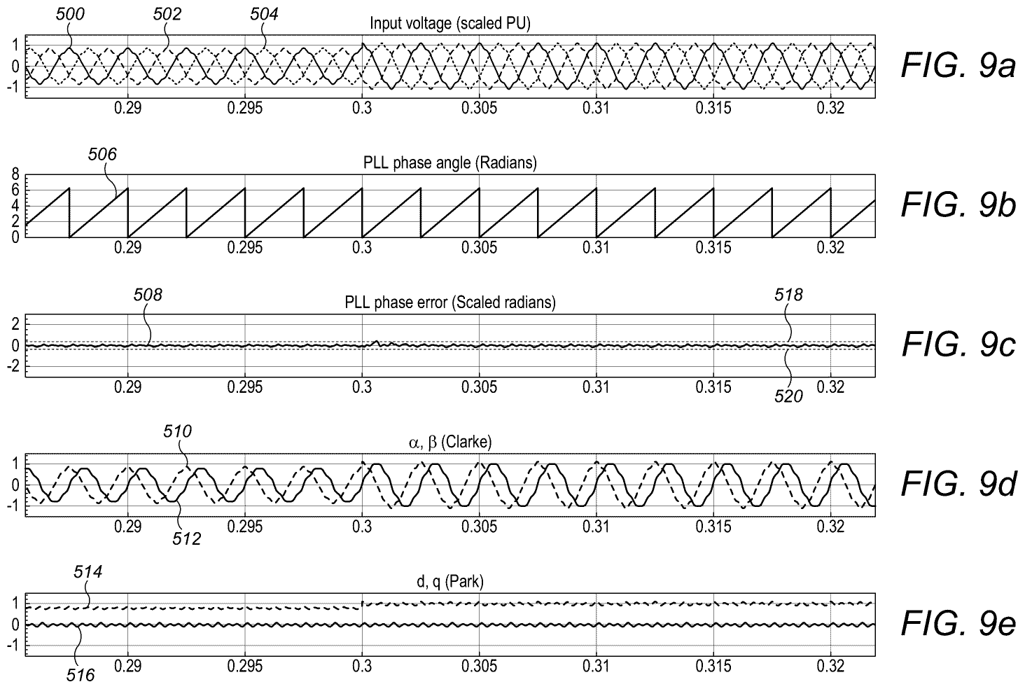

FIGS. 9a to 9e show enlargements of sections of the graphs of FIGS. 8a to 8e respectively, showing the section around t=0.3 when the voltage rise occurs. As can be seen more clearly by comparing FIGS. 9a and 9e, the change in the Park transform ‘d’ value 514 (which represents the PU scaled peak input voltage) and the Park transform ‘q’ value 516 are aligned closely in time to the change in input voltage in FIG. 9a at t=0.3.

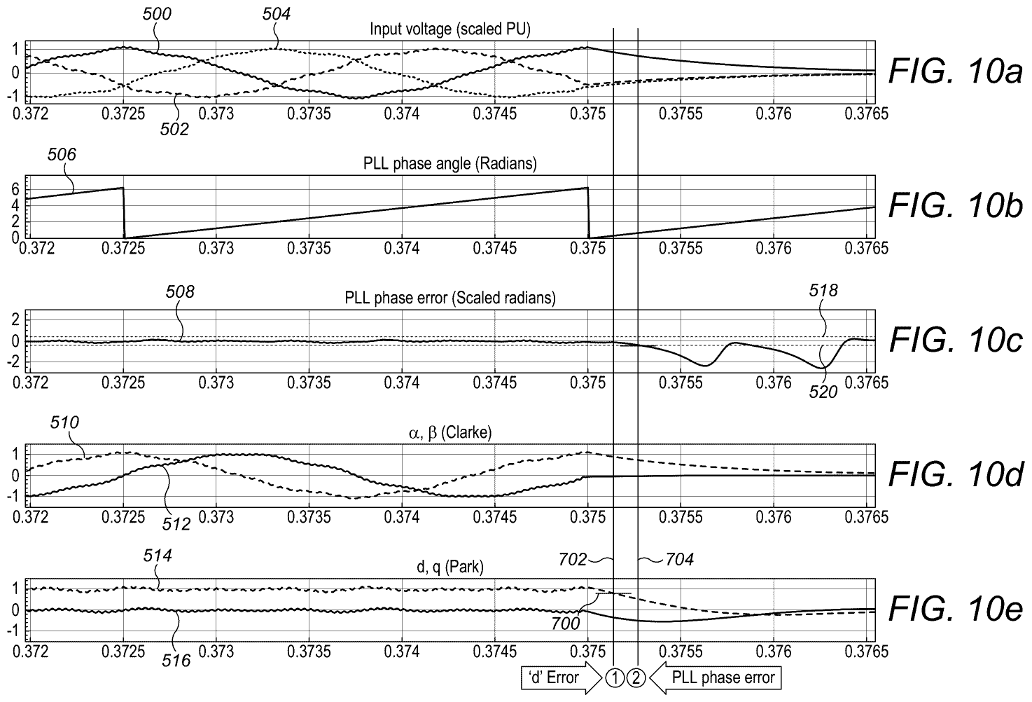

FIGS. 10a to 10e show enlargements of sections of the graphs of FIGS. 8a to 8e respectively, showing the section around t=0.375 when the loss of input power occurs. As can be seen more clearly by comparing FIGS. 10a and 10e, the change in the Park transform ‘d’ value 514 (which represents the PU scaled peak input voltage) is aligned closely in time to the loss of input power of the input voltage in FIG. 10a at t=0.375. Further, by comparing with FIG. 10c it can be seen that even with the harmonic noise the change in the Park transform ‘d’ value 514 drops faster than the phase error 508 of FIG. 10c, and so will detect the loss of input power and trigger a disconnection more quickly in response to the loss of input power when an associated error threshold 700 is crossed at time 702 than will be done by the phase error 508 passing the lower limit line 520 at time 704. Further, the change in the Park transform ‘q’ value 516 also aligned closely in time to the loss of input power of the input voltage in FIG. 10a at t=0.375, and it can be seen that the change in the Park transform ‘q’ value 516 drops faster than the phase error 508 of FIG. 10c, and so will detect the loss of input power and trigger a disconnection more quickly in response to the loss of input power than will be done based on the phase error 508.

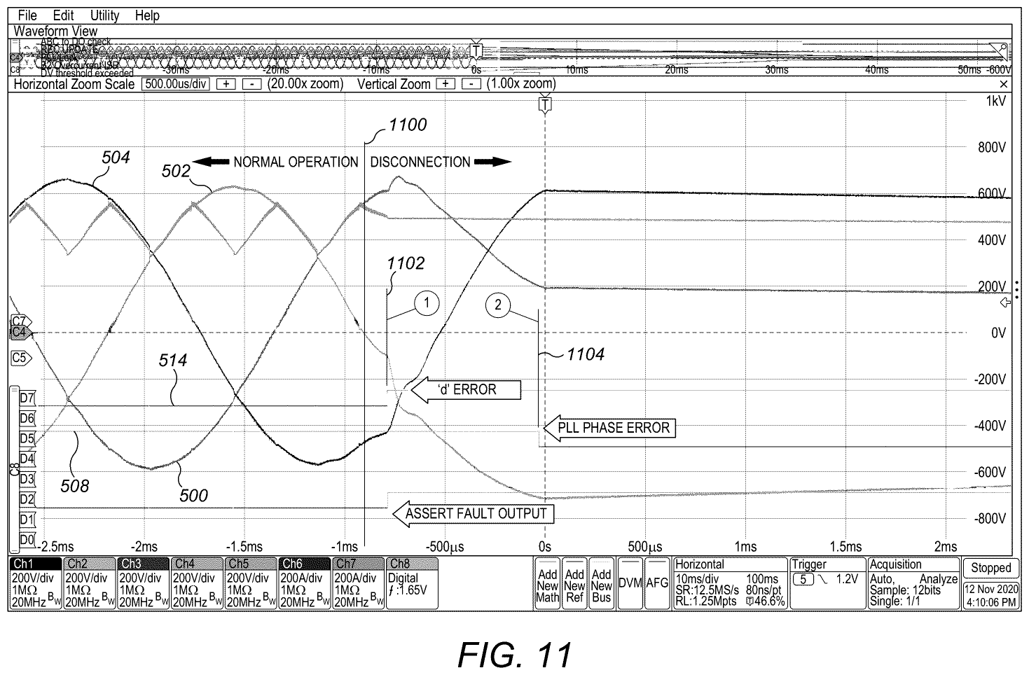

FIG. 11 is a graph showing a third example of experimental results of operation of a fault detection module 108 where a three-phase AC signal at a frequency of 400 Hz and starting with a steady state nominal RMS voltage of 440V is stopped with an exponential decay (This result was obtained from a live equipment circuit breaker isolation/AC source disconnection test) at a time 1100. As can be seen in FIG. 11, the Park transform ‘d’ value 514 responds to the loss of input power at a time 1102, about 700 microseconds before the phase error (F) 508 at a time 1104. Accordingly, it is clear that a change in input power can be detected and used to trigger a disconnection more quickly based on the Park transform ‘d’ value than based on the phase error (F).

In alternative examples, instead of generating outputs indicating that the d value, or other values, are within a predetermined range or not, the feature extraction module 220 may instead generate outputs indicating that the d value, or other values, are within the predetermined range, below the predetermined range, or above the predetermined range. In such examples the assertion mask 226 may define how different outputs from the feature extraction module 220 are combined to determine whether or not the quality of the three-phase AC power signal waveform is acceptable, and whether there is a disconnection condition, with any desired degree of complexity.

In the illustrated embodiment, the fault detection and disconnection system comprises an electrical isolation and scaling unit. This is not essential. In alternative examples, either or both of electrical isolation and/or voltage scaling may be omitted. These may not be required in some examples, depending on the characteristics of the AC signal and the properties of the other parts of the fault detection and disconnection system.

In the illustrated embodiment, the fault detection and disconnection system is used to protect power electronics electrical equipment. In other examples the fault detection and disconnection system may be used with other types of electronic equipment.

In the illustrated embodiment the DDSRF PLL section 202 and the monitoring section 204 are implemented in software. In other examples, some or all parts of these sections may instead comprise dedicated electronic circuitry.

In the illustrated embodiment the fault detection and disconnection system selectively disconnects a single electrical equipment from a single power supply connection. It will be understood that this is by way of example only. In other examples the fault detection and disconnection system may selectively disconnect any number of electrical equipments from any number of power supply connections.

In the illustrated embodiment the fault detection and disconnection system selectively disconnects electrical equipment in response to detection of a fault in a supplied AC power signal. In other examples alternative actions may be taken in response to detection of a fault. In some examples the electrical equipment may be placed in a “safe mode” more resistant to damage caused by a fault instead of being disconnected.

The embodiments described above are fully automatic. In some alternative examples a user or operator of the system may manually instruct some steps of the method to be carried out.

The acts described herein may comprise computer-executable instructions that can be implemented by one or more processors and/or stored on a computer-readable medium or media. The computer-executable instructions can include routines, sub-routines, programs, threads of execution, and/or the like. Still further, results of acts of the methods can be stored in a computer-readable medium, displayed on a display device, and/or the like.

The methods described herein may be performed by software in machine readable form on a tangible storage medium e.g. in the form of a computer program comprising computer program code means adapted to perform all the steps of any of the methods described herein when the program is run on a computer and where the computer program may be embodied on a computer readable medium. Examples of tangible (or non-transitory) storage media include disks, thumb drives, memory cards etc. and do not include propagated signals. The software can be suitable for execution on a parallel processor or a serial processor such that the method steps may be carried out in any suitable order, or simultaneously. This application acknowledges that firmware and software can be valuable, separately tradable commodities. It is intended to encompass software, which runs on or controls “dumb” or standard hardware, to carry out the desired functions. It is also intended to encompass software which “describes” or defines the configuration of hardware, such as HDL (hardware description language) software, as is issued for designing silicon chips, or for configuring universal programmable chips, to carry out desired functions.

Various functions described herein can be implemented in hardware, software, or any combination thereof. If implemented in software, the functions can be stored on or transmitted over as one or more instructions or code on a computer-readable medium. Computer-readable media may include, for example, computer-readable storage media. Computer-readable storage media may include volatile or non-volatile, removable or non-removable media implemented in any method or technology for storage of information such as computer readable instructions, data structures, program modules or other data. A computer-readable storage media can be any available storage media that may be accessed by a computer. By way of example, and not limitation, such computer-readable storage media may comprise RAM, ROM, EEPROM, flash memory or other memory devices, CD-ROM or other optical disc storage, magnetic disc storage or other magnetic storage devices, or any other medium that can be used to carry or store desired program code in the form of instructions or data structures and that can be accessed by a computer. Disc and disk, as used herein, include compact disc (CD), laser disc, optical disc, digital versatile disc (DVD), floppy disk, and Blu-ray (®) disc (BD). Further, a propagated signal is not included within the scope of computer-readable storage media. Computer-readable media also includes communication media including any medium that facilitates transfer of a computer program from one place to another. A connection, for instance, can be a communication medium. For example, if the software is transmitted from a website, server, or other remote source using a coaxial cable, fiber optic cable, twisted pair, DSL, or wireless technologies such as infrared, radio, and microwave are included in the definition of communication medium. Combinations of the above should also be included within the scope of computer-readable media.

Alternatively, or in addition, the functionality described herein can be performed, at least in part, by one or more hardware logic components. For example, and without limitation, hardware logic components that can be used may include Field-programmable Gate Arrays (FPGAs), Program-specific Integrated Circuits (ASICs), Program-specific Standard Products (ASSPs), System-on-a-chip systems (SOCs). Complex Programmable Logic Devices (CPLDs), etc.

It will be understood that the benefits and advantages described above may relate to one embodiment or may relate to several embodiments. The embodiments are not limited to those that solve any or all of the stated problems or those that have any or all of the stated benefits and advantages. Variants should be considered to be included into the scope of the invention.

Any reference to ‘an’ item refers to one or more of those items. The term ‘comprising’ is used herein to mean including the method steps or elements identified, but that such steps or elements do not comprise an exclusive list and a method or apparatus may contain additional steps or elements.

Further, to the extent that the term “includes” is used in either the detailed description or the claims, such term is intended to be inclusive in a manner similar to the term “comprising” as “comprising” is interpreted when employed as a transitional word in a claim.

The order of the steps of the methods described herein is exemplary, but the steps may be carried out in any suitable order, or simultaneously where appropriate. Additionally, steps may be added or substituted in, or individual steps may be deleted from any of the methods without departing from the scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. What has been described above includes examples of one or more embodiments. It is, of course, not possible to describe every conceivable modification and alteration of the above devices or methods for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims.

What is claimed is:

1. A method of monitoring a three-phase alternating current (AC) signal, the method comprising:
carrying out analog to digital (A/D) conversion of each phase of the AC signal to produce respective digital voltage signals;
calculating at least one of a direct component (d) value and a quadrature component (q) value in a rotating reference frame rotating at a fundamental frequency of the AC signal from the digital voltage signals using a Park Transform;
comparing the at least one of the d value and the q value to one or more thresholds; and
based on a result of the comparing, detecting deviation of the AC signal from a desired waveform.

2. The method of claim 1, wherein the calculating comprises applying a Decoupled Double Synchronous Reference Frame Phase Locked Loop (DDSRF PLL) algorithm to the digital voltage signals and obtaining the at least one of the d value and the q value from an output of the Park Transform of the DDSRF PLL algorithm.

3. The method of claim 1, wherein the desired waveform is a predetermined sinusoidal waveform.

4. The method of claim 2, wherein the at least one of the d value and the q value is obtained from a positive sequence Park Transform of the DDSRF PLL algorithm.

5. The method of claim 1, wherein the at least one of the d value and the q value is the d value.

6. The method of claim 1, wherein the comparing comprises determining whether the at least one of the d value and the q value is within a predetermined range by determining whether the at least one of the d value and the q value is between predetermined upper and lower threshold values.

7. The method of claim 6, wherein the deviation of the AC signal from the desired waveform is detected when the at least one of the d value and the q value is not within the predetermined range.

8. The method of claim 2, further comprising per unit (PU) scaling each digital voltage signal before applying the DDSRF PLL algorithm.

9. The method of claim 2, further comprising:
obtaining at least one of a phase error value and an RMS voltage value output by the DDSRF PLL algorithm;
comparing the at least one of the phase error value and the RMS voltage value to one or more additional thresholds; and
detecting deviation of the AC signal from the desired waveform further based on a result of this comparing.

10. The method of claim 1, further comprising:
in response to detecting the deviation from the desired waveform, disconnecting electrical equipment from the AC signal.

11. A system for monitoring a three-phase alternating current (AC) signal, the system comprising:
at least one analog to digital (A/D) converter configured to produce respective digital voltage signals corresponding to each phase of the AC signal; and
at least one processing device configured to:
calculate at least one of a direct component (d) value and a quadrature component (q) value in a rotating reference frame rotating at a fundamental frequency of the AC signal from the digital voltage signals using a Park Transform;
compare the at least one of the d value and the q value to one or more thresholds; and
based on a result of the comparing, detect deviation of the AC signal from a desired waveform.

12. The system of claim 11, wherein, to calculate the at least one of the d value and the q value, the at least one processing device is configured to:
apply a Decoupled Double Synchronous Reference Frame Phase Locked Loop (DDSRF PLL) algorithm to the digital voltage signals; and
obtain the at least one of the d value and the q value from an output of the Park Transform of the DDSRF PLL algorithm.

13. The system of claim 11, wherein the desired waveform is a predetermined sinusoidal waveform.

14. The system of claim 12, wherein the at least one processing device is configured to obtain the at least one of the d value and the q value from a positive sequence Park Transform of the DDSRF PLL algorithm.

15. The system of claim 11, wherein the at least one of the d value and the q value is the d value.

16. The system of claim 15, wherein the at least one processing device is configured to detect the deviation of the AC signal from the desired waveform when the at least one of the d value and the q value is not within a predetermined range.

17. The system of claim 12, further comprising:
a voltage scaler configured to carry out per unit (PU) scaling of each digital voltage signal before application of the DDSRF PLL algorithm.

18. The system of claim 12, wherein the at least one processing device is further configured to:
obtain at least one of a phase error value and an RMS voltage value output by the DDSRF PLL algorithm;
compare the at least one of the phase error value and the RMS voltage value to one or more additional thresholds; and
detect deviation of the AC signal from the desired waveform further based on a result of this comparing.

19. The system of claim 11, further comprising:
a disconnection module configured to disconnect electrical equipment from the AC signal in response to the detection of the deviation.

20. A non-transitory computer-readable medium containing instructions that, when executed by one or more processors, cause the one or more processors to:
obtain respective digital voltage signals from analog to digital (A/D) conversion of each phase of a three-phase alternating current (AC) signal;
calculate at least one of a direct component (d) value and a quadrature component (q) value in a rotating reference frame rotating at a fundamental frequency of the AC signal from the digital voltage signals using a Park Transform;
compare the at least one of the d value and the q value to one or more thresholds; and
based on a result of the comparing, detect deviation of the AC signal from a desired waveform.
